(19) United States
(12) Patent Application Publication
(10) Pub. No.: US 2008/0280439 A1
(43) Pub. Date: Nov. 13, 2008

(54) OPTIMAL CONCENTRATION OF PLATINUM IN A NICKEL FILM TO FORM AND STABILIZE NICKEL MONOSILICIDE IN A MICROELECTRONIC DEVICE

(75) Inventors: Loeizig Ehouarne, Chateauneuf les Marigues (FR); Dominique Mangelinck, Marseille (FR); Magali Putero, Marseille (FR); Carine Perrin, Marseille (FR); Khalid Hoummada, Marseille (FR); Romain Coppard, Rousset (FR)

Correspondence Address: SCHWEGMAN, LUNDBERG & WOESSNER / ATMEL, P.O. BOX 2938, MINNEAPOLIS, MN, 55402, US

(73) Assignee: Atmel Corporation, San Jose, CA (US)

(21) Appl. No.: 11/745,589

(22) Filed: May 8, 2007

(51) Int. Cl. H01L 21/44

(52) U.S. Cl. 438/683; 438/682; 257/E21.593

(57) ABSTRACT

A method of forming a nickel monosilicide layer on silicon-containing features of an electronic device that includes depositing a nickel film over the silicon-containing features. The nickel film is co-deposited with a selected material. The selected material has an atomic percentage in a range of about 10% to 25%. A single anneal step is then applied to the nickel film thus directly forming the nickel monosilicide layer.

### TECHNICAL FIELD

The invention relates generally to a process for fabricating an integrated circuit structure, and more specifically to a fabrication process for directly forming nickel monosilicide (NiSi).

### BACKGROUND ART

In the semiconductor processing art, low resistivity metal silicide regions are commonly formed on silicon-containing features to enable efficient electrical interconnection of components in an electronic device. Silicides are compound materials formed from a chemical reaction between various forms of silicon (e.g., single-crystal or polycrystalline) with a metal. Self-aligned silicides (referred to as salicides) are formed on silicon-containing features, such as transistor gates and source/drain regions, to provide a layer of low resistivity material on the feature.

For example, nickel monosilicide (NiSi) is often used as a contact material in silicon-based fabrication. NiSi has a resistivity of 14-20 μohm-cm and is thus comparable to titanium silicide (TiSi₂) and cobalt silicide (CoSi₂). Moreover, NiSi has the lowest formation temperature of the three silicides—roughly 350° C. to 750° C. Further, NiSi consumes less silicon (about 1.82 nm of Si is consumed per nm of metal) than the other two compounds. Nickel silicide has three main phases depending on formation temperature (Ni₂Si, NiSi, and NiSi₂). Nickel monosilicide (NiSi) is the desired phase partially due to its having the lowest resistivity of the three phases.

In a self-aligned silicide processing method, a blanket metal is deposited on exposed portions of silicon-containing features. The metal is then reacted with portions of the features to form silicide regions. Portions of the features that are not exposed, for example, portions covered by a spacer, do not form a silicide region. In this manner, self-aligned silicides are selectively formed on the features without patterning or etching silicide to define low resistivity regions. As discussed above, self-aligned silicides can be formed from metals that include nickel, titanium, cobalt, as well as other metals that react with silicon to form silicides.

With reference to FIGS. 1A-1C, a one-step rapid thermal anneal (RTA) process of the prior art is a conventional method of fabricating a self-aligned silicide structure. FIG. 1A includes a substrate 101, doped active regions 103A contained within the substrate 101, and a silicon-containing feature 105A. The substrate 101 is typically a silicon wafer. The silicon-containing feature 105A may be, for example, a polysilicon gate region of a transistor. The silicon-containing feature 105A has adjacent spacers 107. The adjacent spacers 107 are typically fabricated from silicon dioxide, silicon nitride, or another dielectric material. The doped active regions 103A may serve as a source and drain of the transistor.

In FIG. 1B, a layer of a silicide-forming metal 109 (or alternatively, a metal alloy) is blanket-deposited over exposed portions of the substrate 101 and the silicon-containing feature 105A. A high temperature RTA process step is applied, typically at temperatures exceeding 500° C. The high temperature RTA step causes the silicide-forming metal 109 to react with the exposed portions of the substrate 101 and the silicon-containing feature 105A. Subsequent to the high temperature RTA step and referring now to FIG. 1C, a low resistivity metal silicide 111 is formed. A portion of the material composition of various structures has changed, thus forming silicided doped active regions 103B and a silicided feature 105B.

In another conventional prior art process (not shown but similar to FIGS. 1A-1C) known as a two-step RTA process, a silicide-forming metal or metal alloy is deposited at room temperature on silicon-containing features. A first low temperature annealing process is performed at temperatures typically less than about 300° C. forming a high resistivity metal silicide layer over the active regions and any silicon-containing features. Any unreacted metal is removed by a wet etch process step. Subsequently, a second higher temperature anneal is performed at temperatures exceeding 450° C., thus forming a low resistivity metal silicide layer. However, a nickel silicide layer generally exhibits poor thermal stability at higher temperatures (e.g., temperatures above 700° C.) due to agglomeration and/or NiSi₂ formation. Thus, such a nickel silicide layer becomes ineffective as a low resistivity layer eventually causing device failure. Additionally, Ni diffuses readily on edges of spacers, potentially causing edge effects and high leakage currents. The Ni diffusion is most pronounced with one-step RTA processes.

As semiconductor technology advances, smaller feature sizes (i.e., smaller design rules) have become increasingly important. Smaller feature sizes allow an increased density of electronic devices and concomitant increases in execution speeds. However, neither the one-step nor the two-step RTA processes are adequate for silicidation steps at extremely small design rules. For example, the one-step RTA process is particularly troublesome for certain silicide-forming metals, such as nickel. At rapid thermal anneal temperatures ranging from 350° C. to 700° C., the reaction rate between the nickel and silicon is difficult to control, resulting in an excessive formation of nickel silicide. Control of the reaction rate can be especially problematic with metals such as cobalt and titanium. As indicated by FIG. 2, the excessive formation of cobalt or titanium silicide 201 can lead to undesirable bridging 203, thus creating a direct short of low resistivity material between, for example, source, gate, and drain regions.

FIG. 3 indicates effects of Ni diffusion in certain geometries. Smaller (or short) features 105D tend to convert entirely or nearly entirely into nickel silicide 301 while larger (or taller) features 105C are only partially converted. Conversion of the entire smaller feature 105D to nickel silicide 301 is undesirable but inevitable given size differences between the larger feature 105C and the smaller feature 105D. The silicide conversion rate due to the size difference is exacerbated by the uncontrollable reaction rates at the high anneal temperatures of the prior art.

Further, particular metals present certain challenges. For example, the use of titanium in the two-step RTA process to form titanium silicide (TiSi₂) in a self-aligned manner is ineffective with smaller semiconductor structures. Neither titanium metals nor titanium alloys fully react with small areas of silicon. Referring to FIG. 4, the reaction mechanism between titanium and silicon is by nucleation, and therefore agglomerated clusters 401 of titanium silicide form. (Similar results can occur with nickel, but due to a reduction in interfacial energy.) The agglomerated clusters 401 are scattered and inconsistent. Therefore, the agglomerated clusters 401 do not adequately lower the resistivity of the silicon-based components of the semiconductor device and, consequently, do not form a useful silicide.

Cobalt is also used to react with silicon (not shown) to form self-aligned cobalt silicide (CoSi₂) regions utilizing a two-step RTA process. However, temperatures at which the first and second anneals are performed are relatively high. For example, the first anneal for cobalt is typically at temperatures ranging from 450° C. to 510° C. The second anneal is at temperatures ranging from 760° C. to 840° C. These high temperatures induce stress on the semiconductor structure and can destroy functionality of the semiconductor device. Additionally, these relatively high temperatures may not be compatible or desirable with either pre-existing components of the device or subsequent fabrication steps. More particularly, these high temperatures may deleteriously diffuse materials of the existing semiconductor device.

Formation of CoSi₂ has two additional problems. First, formation of CoSi₂ as a silicide has a large silicon consumption rate. The large consumption rate is especially problematic with varying silicon feature sizes (discussed above with reference to FIG. 3). Further, CoSi₂ has inherently large interfacial roughness levels which can contribute to junction leakage. The consumption rate combined with the interfacial roughness severely restrict the use of CoSi₂ in ultra-shallow junction devices.

Accordingly, what is needed is a method to control formation rates of silicides to reduce silicide formation in and around the features, reduce interfacial roughness due to the silicide growth, and produce thermally stable and low resistivity silicides.

### SUMMARY

In an exemplary embodiment, the invention is a method of forming a nickel monosilicide layer on silicon-containing features of an electronic device. The method includes depositing a nickel film over the silicon-containing features where the nickel film is co-deposited with a selected material. The selected material is chosen to have an atomic percentage in a range of about 10% to 25%. The nickel film is then reacted with the underlying silicon-containing features in a single anneal step to directly form the nickel monosilicide layer.

In another exemplary embodiment, the invention is a method of forming a nickel monosilicide layer on silicon-containing features of an electronic device where the method includes depositing a nickel film over the silicon-containing features. The nickel film is co-deposited with a selected material chosen from a group including platinum, palladium, zirconium, and germanium. The selected material has an atomic percentage in a range of about 10% to 15%. A single anneal step of less than about 500° C. is applied to the nickel film to directly form the nickel monosilicide layer.

In another exemplary embodiment, the invention is a method of forming a nickel monosilicide layer on silicon-containing features of an electronic device where the method includes depositing a nickel film over the silicon-containing features. The nickel film is co-deposited with platinum. The platinum is chosen to have an atomic percentage in a range of about 10% to 25%. A single anneal step in a range of 250° C. to 350° C. is applied to the nickel film to directly form the nickel monosilicide layer without first forming any other nickel silicide phase.

In another exemplary embodiment, the invention is a method of forming a nickel monosilicide layer on silicon-containing features of an electronic device where the method includes depositing a nickel film over the silicon-containing features. The nickel film is co-deposited with a selected material chosen from a group including platinum, palladium, zirconium, germanium, tungsten, tantalum, and titanium. The selected material has an atomic percentage in a range of about 10% to 15%. A single anneal step of less than about 500° C. is applied to the nickel film to directly form the nickel monosilicide layer.

### BRIEF DESCRIPTION OF THE DRAWINGS

FIGS. 1A-1C are processes involved in one-step high temperature rapid thermal annealing of the prior art for fabricating a self-aligned silicided electronic device.

FIG. 2 shows excessive formation of titanium or cobalt silicide causing bridging of low resistivity material in a prior art process.

FIG. 3 shows non-uniformity in silicidation processes of the prior art due to silicon feature size differences.

FIG. 4 shows nucleation sites of titanium and silicon due to reaction mechanisms of the prior art.

FIGS. 5A-5C are one-step rapid thermal annealing steps for fabricating a self-aligned silicided electronic device in accordance with embodiments of the present invention.

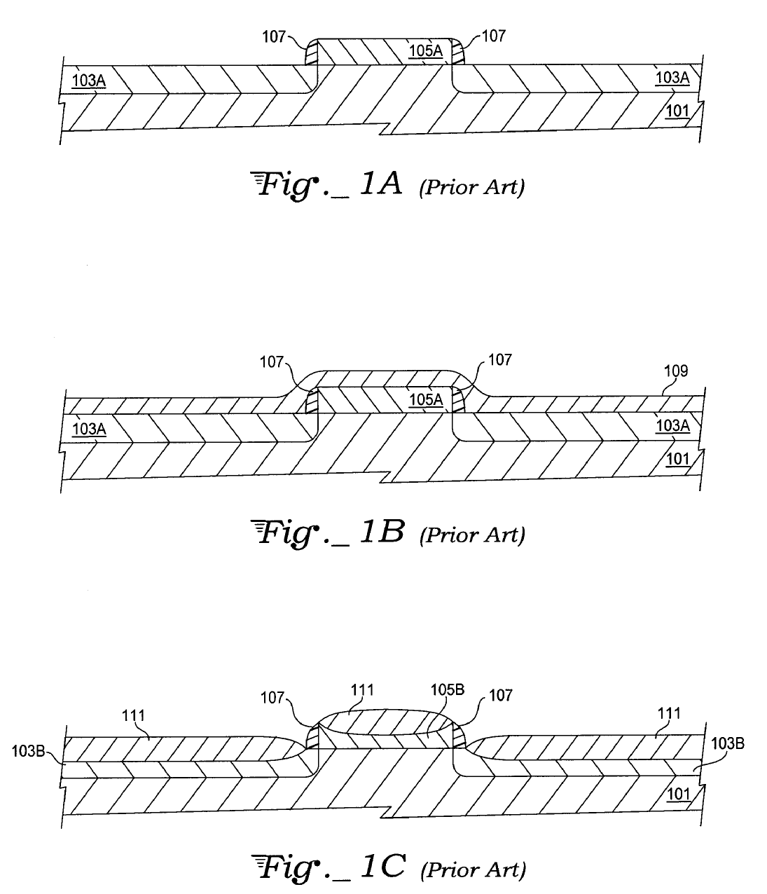

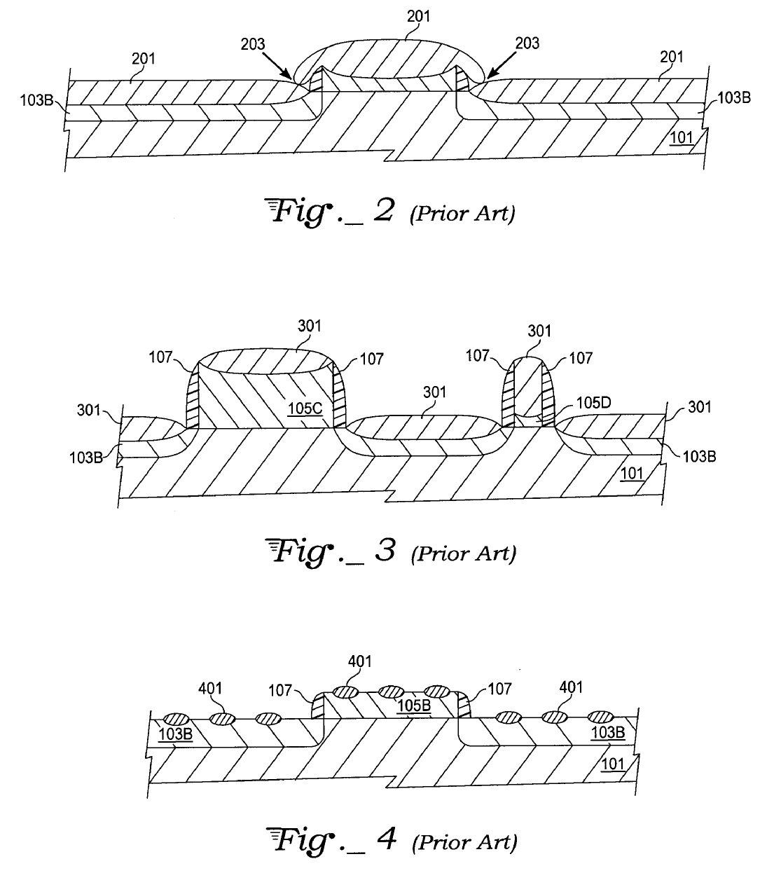

### DETAILED DESCRIPTION

As described above, self-aligned silicidation (salicidation) is widely used in integrated circuit fabrication to reduce single-crystal and polycrystalline silicon interconnect and contact resistance values. The nickel monosilicide formation process of the present invention has a sheet resistance value which remains constant for linewidths as small as 30 nm and has a low silicon consumption rate. Unlike the prior art, which typically forms NiSi from a metal-rich Ni₂Si phase, NiSi is produced directly. Further, various embodiments include an alloy and a composition for a salicide process based on NiSi. In one embodiment, the alloy is comprised of nickel with a platinum (Pt) concentration of between about 10 atomic percent and 15 atomic percent. In other embodiments, other elements such as palladium, zirconium, germanium, tungsten, tantalum, or titanium are used with Ni in atomic percentages of between about 10% and 25%. (Note that an important distinction is made between atomic percentage and percentage by weight. For example, 15% Pt by weight in 85% Ni by weight corresponds to 5 atomic % Pt in 95 atomic % Ni. Therefore atomic percentages will be used exclusively and designated as “at. %” herein.)

In an exemplary embodiment, one or more NiPt layers are formed over silicon-containing areas of a semiconductor device. The one or more layers may be co-deposited (e.g., co-sputtered) from separate Ni and Pt targets and are formed with 10 at. % to 15 at. % Pt. The separate targets are typically pure Ni and pure Pt. Alternatively, the layers may be co-deposited from a single target comprised of Ni₁₋ₓPtₓ such that a proportion of Pt is produced from 10 at. % to 15 at. %.

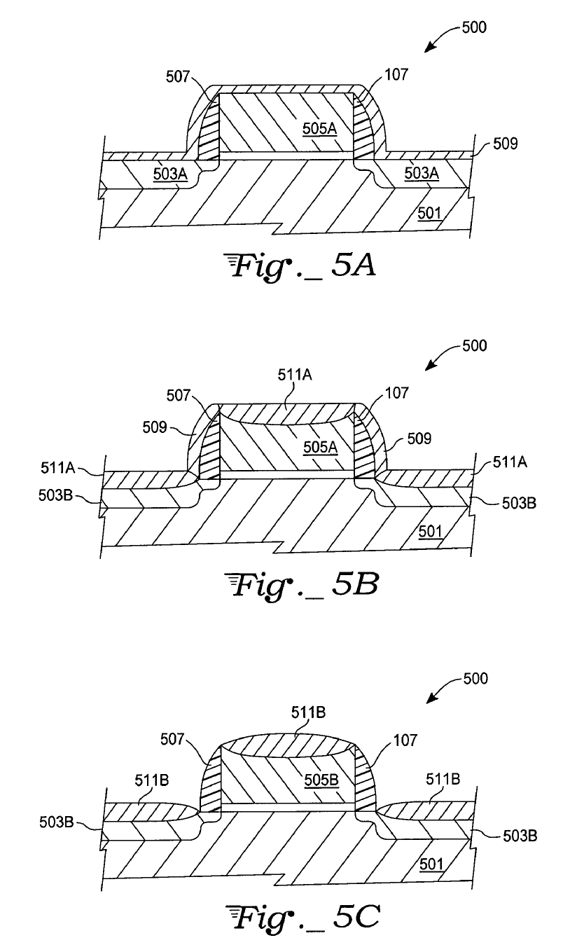

Referring to FIG. 5A, a portion of a semiconductor device 500 includes a substrate 501, one or more doped silicon-containing regions 503A, and a silicon-containing feature 505A. The portion of the semiconductor device 500 may be any portion of a typical integrated circuit. For illustrative purposes only, the semiconductor device 500 may be considered to be a portion of a floating gate memory cell or a field-effect transistor.

The substrate 501 may be comprised of various materials known in the semiconductor art. Such materials include silicon (or other group IV semiconducting materials), compound semiconductors (e.g., compounds of elements, especially elements from periodic table Groups III-V and II-VI), quartz photomasks (e.g., with a deposited and annealed polysilicon layer or a deposited/sputtered metal layer over one surface), or other suitable materials. Frequently, the substrate 501 will be selected based upon an intended use of a finalized semiconducting product. For example, a memory cell used as a component in an integrated circuit for a computer may be formed on a silicon wafer. A memory cell used for lightweight applications or flexible circuit applications, such as a cellular telephone or personal data assistant (PDA), may form the memory cell on a polyethyleneterephthalate (PET) substrate deposited with silicon dioxide and polysilicon followed by an excimer laser annealing (ELA) anneal step. For purposes of exemplary embodiments described herein, only the doped silicon-containing regions 503A, and the silicon-containing feature 505A need be comprised at least partially of silicon. In a specific exemplary embodiment, the substrate 501 may be selected to be a silicon wafer. A preferential chemical etch or, alternatively, an in-situ sputter etch may be applied to the substrate 501 prior to any metal deposition steps.

Spacers 507 are formed along sidewalls of the silicon-containing feature 505A. Fabrication of the spacers 507 is known in the art. The spacers 507 are frequently formed from a dielectric material such as a chemical vapor deposition (CVD) deposited silicon dioxide. A blanket metal layer 509 is formed over the semiconductor device 500. The blanket metal layer 509, as described above, may be co-deposited from separate Ni and Pt targets and is formed with 10 at. % to 15 at. % Pt or may be co-deposited from a single target comprised of Ni₁₋ₓPtₓ. In a specific exemplary embodiment, a power density applied to the one or more targets is between two and ten watts/cm² with an ambient argon partial pressure of between 0.5 to 5 millitorr. The blanket metal layer 509 is formed to a thickness of between 1 nm and 100 nm but may vary depending upon device type, design rules, and other factors which may be readily determined by a skilled artisan.

In FIG. 5B, an RTA step is applied to the semiconductor device 500. The addition of Pt in a range of 10 at. % to 15 at. % (or various other elements as described herein) allows for a single anneal step directly forming a nickel monosilicide (NiSi) layer 511A without first forming the metal-rich Ni₂Si phase. The direct formation of the NiSi layer 511A has several advantages including limiting or eliminating edge effects and limiting the thermal budget since subsequent anneal steps are not required. Additionally, a single anneal step advantageously is easier to integrate into a fabrication process, more robust, and is less expensive. Thermal stability of the NiSi layer 511A is also increased by reducing or eliminating any agglomeration problems inherent in the prior art (similar problems can occur in the prior art with nickel agglomeration as with titanium, see FIG. 4). Further, using Ni and Pt or Ni₁₋ₓPtₓ to form the NiSi layer 511A also reduces interfacial roughness levels, thus allowing use of the NiSi layer 511A in electronic devices having ultra-shallow junctions.

In a specific exemplary embodiment, the RTA step is performed at between 250° C. to 350° C. The RTA step produces partially-consumed doped silicon-containing regions 503B and a silicon-containing feature 505B. However, in other specific exemplary embodiments, temperatures as high as 500° C. may be employed. Temperatures greater than 600° C. (including back-end-of-line processes) are generally not employed primarily for three reasons: (1) the NiSi layer can agglomerate at temperatures around 500° C. to 600° C. causing a discontinuous NiSi layer with Ni islands formed as described above; (2) an enhanced grain growth of silicon due to the higher temperature may lead to an inversion phenomenon resulting in large grains of silicide across polycrystalline silicon; and (3) a high resistivity Ni₂Si phase of silicide is formed above about 750° C. These phenomena increase the contact resistance of the film, increase interfacial roughness levels, and decrease the thermal stability of the NiSi film and are therefore unacceptable for advanced semiconductor processing. These high temperature results will occur with any NiSi film. Advantageously, the present invention limits or eliminates such concerns.

Referring now to FIG. 5C, a selective etchant is used to remove any excess amounts of the metal layer 509. The NiSi film 511B may serve as a low resistivity contact layer for subsequent fabrication steps.

In the foregoing specification, the present invention has been described with reference to specific embodiments thereof. It will, however, be evident to a skilled artisan that various modifications and changes can be made thereto without departing from the broader spirit and scope of the invention as set forth in the appended claims. For example, skilled artisans will appreciate that various types of annealing treatments other than RTA may be employed. Additionally, sputtering power densities, partial pressures, film thicknesses, and other fabrication details are merely exemplary and may be changed for a particular device type or fabrication environment as needed and known by one of skill in the art. The specification and drawings are, accordingly, to be regarded in an illustrative rather than a restrictive sense.

What is claimed is:

1. A method of forming a nickel monosilicide layer on silicon-containing features of an electronic device, the method comprising:
depositing a nickel film over the silicon-containing features, the nickel film being co-deposited with a selected material, the selected material having an atomic percentage in a range of about 10% to 25%; and
reacting the nickel film with the underlying silicon-containing features in a single anneal step, thereby directly forming the nickel monosilicide layer.

2. The method of claim 1 wherein the selected material is chosen to be platinum.

3. The method of claim 2 wherein the platinum has an atomic percentage in a range of about 10% to 15%.

4. The method of claim 2 wherein the nickel film is deposited by sputtering metal from separate nickel and platinum targets.

5. The method of claim 2 wherein the nickel film is deposited by sputtering metal from a single target containing Ni₁₋ₓPtₓ, the proportions of nickel and platinum being chosen such that platinum comprises 10 atomic percent to 15 atomic percent of the target.

6. The method of claim 1 wherein the selected material is chosen to be palladium.

7. The method of claim 1 wherein the selected material is chosen to be zirconium.

8. The method of claim 1 wherein the selected material is chosen to be germanium.

9. The method of claim 1 wherein the selected material is chosen from the group consisting of tungsten, tantalum, and titanium.

10. The method of claim 1 wherein a temperature of the anneal step is selected to be in a range of 250° C. to 350° C.

11. A method of forming a nickel monosilicide layer on silicon-containing features of an electronic device, the method comprising:
depositing a nickel film over the silicon-containing features, the nickel film being co-deposited with a selected material, the selected material being chosen from the group consisting of platinum, palladium, zirconium, and germanium, the selected material having an atomic percentage in a range of about 10% to 15%; and
applying a single anneal step of less than about 500° C. to the nickel film thereby directly forming the nickel monosilicide layer.

12. The method of claim 11 wherein a temperature of the single anneal step is selected to be in a range of 250° C. to 350° C.

13. A method of forming a nickel monosilicide layer on silicon-containing features of an electronic device, the method comprising:
depositing a nickel film over the silicon-containing features, the nickel film being co-deposited with platinum, the platinum having an atomic percentage in a range of about 10% to 25%; and
applying a single anneal step to the nickel film thereby directly forming the nickel monosilicide layer without first forming any other nickel silicide phase, the single anneal step being selected to be in a range of 250° C. to 350° C.

14. The method of claim 13 wherein the nickel film is deposited by sputtering metal from separate nickel and platinum targets.

15. The method of claim 13 wherein the nickel film is deposited by sputtering metal from a single target containing Ni₁₋ₓPtₓ, the proportions of nickel and platinum being chosen such that platinum comprises 10 atomic percent to 15 atomic percent of the target.

16. A method of forming a nickel monosilicide layer on silicon-containing features of an electronic device, the method comprising:
depositing a nickel film over the silicon-containing features, the nickel film being co-deposited with a selected material, the selected material being chosen from the group consisting of platinum, palladium, zirconium, germanium, tungsten, tantalum, and titanium, the selected material having an atomic percentage in a range of about 10% to 15%; and
applying a single anneal step of less than about 500° C. to the nickel film thereby directly forming the nickel monosilicide layer.

17. The method of claim 16 wherein a temperature of the single anneal step is selected to be in a range of 250° C. to 350° C.
